(19) United States
(12) Patent Application Publication
(10) Pub. No.: US 2025/0101263 A1
(43) Pub. Date: Mar. 27, 2025

(54) POLISHING COMPOSITIONS AND METHODS OF USE THEREOF

(71) Applicant: Fujifilm Electronic Materials U.S.A., Inc., N. Kingstown, RI (US)

(72) Inventors: Eric Turner, Phoenix, AZ (US); Changhong Wu, Mesa, AZ (US); Bin Hu, Chandler, AZ (US); Hyosang Lee, Chandler, AZ (US)

(21) Appl. No.: 18/889,658

(22) Filed: Sep. 19, 2024

Related U.S. Application Data
(60) Provisional application No. 63/540,745, filed on Sep. 27, 2023.

(51) Int. Cl. C09G 1/02; H01L 21/321

(52) U.S. Cl. CPC C09G 1/02; H01L 21/3212

(57) ABSTRACT

The present document relates to a polishing composition that includes at least one abrasive, at least one pH adjuster, at least one guanamine compound, and water. The polishing composition can be used in a method of polishing a substrate including applying the polishing composition to a surface of a substrate and bringing a pad into contact with the surface of the substrate and moving the pad in relation to the substrate. The surface of the substrate can include tungsten and/or molybdenum.

### CROSS-REFERENCE TO RELATED APPLICATION

The present application claims priority to U.S. Provisional Application Ser. No. 63/540,745, filed on Sep. 27, 2023, the contents of which are hereby incorporated by reference in their entirety.

### BACKGROUND

The semiconductor industry is continually driven to improve chip performance by further miniaturization of devices through process and integration innovations. Chemical Mechanical Polishing/Planarization (CMP) is a powerful technology as it makes many complex integration schemes at the transistor level possible, thereby facilitating increased chip density.

CMP is a process used to planarize/flatten a wafer surface by removing material using abrasion-based physical processes concurrently with surface-based chemical reactions. In general, a CMP process involves applying a CMP slurry (e.g., an aqueous chemical formulation) to a wafer surface while contacting the wafer surface with a polishing pad and moving the polishing pad in relation to the wafer. Slurries can typically include an abrasive component and dissolved chemical components, which can vary significantly depending upon the materials (e.g., metals, metal oxides, metal nitrides, dielectric materials such as silicon oxide, silicon nitride, etc.) present on the wafer that will be interacting with the slurry and the polishing pad during the CMP process.

Many currently available CMP slurries were specifically designed to remove materials more common in older chip designs. However, chip designs and architectures are constantly changing and certain components in these older CMP slurries may cause deleterious and/or unacceptable defect counts.

### SUMMARY

This summary is provided to introduce a selection of concepts that are further described below in the detailed description. This summary is not intended to identify key or essential features of the claimed subject matter, nor is it intended to be used as an aid in limiting the scope of the claimed subject matter.

As defined herein, unless otherwise noted, all percentages expressed should be understood to be percentages by weight to the total weight of the chemical mechanical polishing composition.

In one aspect, the present disclosure features a polishing composition that includes at least one abrasive, at least one pH adjuster (e.g., selected from an acid, a base, or a mixture thereof), at least one guanamine compound, and a solvent (e.g., water).

In some embodiments, the guanamine compound includes a structure of formula (I):

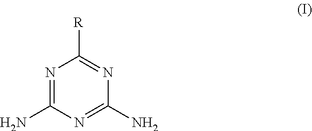

or a salt thereof,
wherein R can be any described herein.

In some embodiments, the guanamine compound includes a structure of formula (IA):

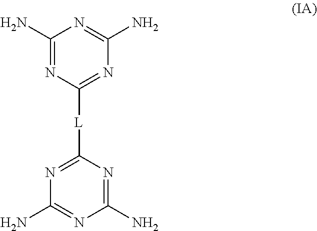

or a salt thereof,
wherein L can be any described herein.

In another aspect, the present disclosure features a method of polishing a substrate, the method including the steps of: applying a polishing composition described herein to a surface of a substrate; and bringing a pad into contact with the surface of the substrate and moving the pad in relation to the substrate.

Other aspects and advantages of the claimed subject matter will be apparent from the following description and the appended claims.

### DETAILED DESCRIPTION

Embodiments disclosed herein relate generally to compositions and methods of using said compositions to polish semiconductor substrates (e.g., wafers). In one or more embodiments, the compositions disclosed herein may be used to polish semiconductor substrates that include at least a tungsten portion and, more specifically, may include at least tungsten and silicon oxide and/or silicon nitride portions. In one or more embodiments, the polishing compositions described herein may provide relatively low static etch rates (SER) for metals, particularly tungsten, while not significantly decreasing their removal rates. The ability to lower the SER is important as it may reduce defects and other undesirable outcomes from occurring during a polishing process.

In one or more embodiments, the polishing composition described herein includes at least one abrasive, at least one pH adjuster selected from the group consisting of an acid, a base, or a mixture thereof, and at least one guanamine compound, wherein the guanamine compound includes a structure of formula (I):

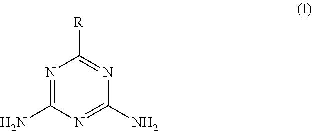

or a salt thereof,
where R is a group that comprises an optionally substituted aliphatic (e.g., optionally substituted alkyl), an optionally substituted aromatic (e.g., optionally substituted aryl), optionally substituted heterocyclyl (e.g., optionally substituted triazinyl), or optionally substituted arylalkyl, and water.

In one or more embodiments, the guanamine compound comprises a structure of formula (IA):

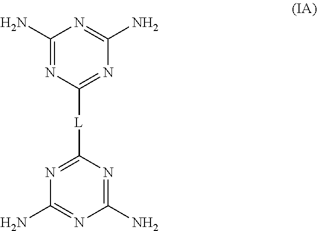

or a salt thereof,
where L is a linker (e.g., optionally substituted aliphatic, optionally substituted heteroaliphatic, or a combination thereof, as well as any described herein). In some embodiments, L is

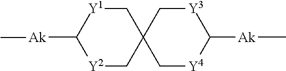

or -Ak-; each Ak is, independently, a covalent bond, optionally substituted aliphatic (e.g., optionally substituted alkylene), or optionally substituted heteroaliphatic (e.g., optionally substituted heteroalkylene); and each of Y¹, Y², Y³, and Y⁴ is, independently, alkylene (e.g., —CR^{C1}R^{C2}—), oxy (—O—), thio (—S—), or imino (—NR^{N1}—).

In one or more embodiments, a polishing composition according to the present disclosure can include from about 0.1% to about 50% by weight abrasive, about 0.001% to about 10% by weight acid, base, or mixture thereof, about 0.1 ppm to about 1000 ppm of a guanamine compound (e.g., any described herein), and the remaining percent by weight (e.g., from about 40% to about 99.9% by weight) of solvent (e.g., deionized water). Optionally, the polishing composition described herein can include at least one amino acid or a poly(amino acid), distinct from the acid, in an amount of from about 0.001% to about 1% by weight of the composition, and/or at least one nitride inhibiting compound in an amount of from about 0.1 ppm to about 1000 ppm of the composition.

In one or more embodiments, the present disclosure provides a concentrated polishing composition that can be diluted with water prior to use by up to a factor of two, or up to a factor of four, or up to a factor of six, or up to a factor of eight, or up to a factor of ten. In other embodiments, the present disclosure provides a point-of-use (POU) polishing composition comprising the above-described polishing composition, water, and optionally an oxidizer for use on a substrate (e.g., a substrate containing a tungsten portion).

In one or more embodiments, a POU polishing composition can include from about 0.1% to about 12% by weight abrasive, from about 0.001% to about 5% by weight pH adjuster, from about 0.1 ppm to about 500 ppm by weight of a guanamine compound (e.g., any described herein), optionally about 0.1% to about 5% by weight oxidizer, and the remaining weight percent (e.g., from about 88% to about 99% by weight) of solvent (e.g., deionized water). Further, the POU polishing composition described herein can optionally include at least one amino acid or a poly(amino acid), distinct from the acid, in an amount of from about 0.0001% to about 0.5% by weight of the composition, and/or at least one nitride inhibiting compound in an amount of from about 0.1 ppm to about 500 ppm of the composition.

In one or more embodiments, a concentrated polishing composition can include from about 1% to about 50% by weight abrasive, about 0.01% to about 10% by weight pH adjuster, about 1 ppm to about 1000 ppm of a guanamine compound (e.g., any described herein), and the remaining percent by weight (e.g., from about 40% to about 99.9% by weight) of solvent (e.g., deionized water). Optionally, the polishing composition described herein can include at least one amino acid or a poly(amino acid), distinct from the acid, in an amount of from about 0.001% to about 1% by weight of the composition, and/or at least one nitride inhibiting compound in an amount of from about 1 ppm to about 1000 ppm of the composition.

In one or more embodiments, the polishing composition described herein can include at least one (e.g., two or three) abrasive. In one or more embodiments, the polishing composition can include a single type of abrasive. In some embodiments, the at least one abrasive is selected from the group consisting of cationic abrasives, substantially neutral abrasives, and anionic abrasives. In one or more embodiments, the at least one abrasive is selected from the group consisting of alumina, silica, titania, ceria, zirconia, co-formed products thereof (i.e., co-formed products of alumina, silica, titania, ceria, or zirconia), coated abrasives, surface modified abrasives, and mixtures thereof. In some embodiments, the at least one abrasive does not include ceria, a multicomponent abrasive (e.g., a composite abrasive), or an abrasive surface modified by a Si-containing compound (e.g. a silane). In some embodiments, the at least one abrasive is of high-purity, and can have less than about 100 ppm of alcohol, less than about 100 ppm of ammonia, and/or less than about 100 parts per billion (ppb) of an alkali cation such as sodium cation.

In some embodiments, the at least one abrasive is in an amount of from at least about 0.1% (e.g., at least about 0.5%, at least about 1%, at least about 2%, at least about 4%, at least about 5%, at least about 10%, at least about 12%, at least about 15%, or at least about 20%) by weight to at most about 50% (e.g., at most about 45%, at most about 40%, at most about 35%, at most about 30%, at most about 25%, at most about 20%, at most about 15%, at most about 12%, at most about 10%, or at most about 5%) by weight of the polishing composition described herein.

In one or more embodiments, the at least one abrasive can have a mean particle size of from at least about 1 nm (e.g., at least about 5 nm, at least about 10 nm, at least about 20 nm, at least about 40 nm, at least about 50 nm, at least about 60 nm, at least about 80 nm, or at least about 100 nm) to at most about 1000 nm (e.g., at most about 800 nm, at most about 600 nm, at most about 500 nm, at most about 400 nm, at most about 200 nm, at most about 150 nm, or at most about 100 nm). As used herein, the mean particle size (MPS) is determined by dynamic light scattering techniques.

In one or more embodiments, the polishing composition described herein can include at least one (e.g., two or three) pH adjuster that is selected from the group consisting of an acid, a base, or a mixture thereof. In one or more embodiments, the polishing composition described herein can include a single pH adjuster. In one or more embodiments, the at least one pH adjuster is a base selected from inorganic bases, organic bases, and mixtures thereof. In some embodiments, the inorganic base can be selected from the group consisting of ammonium hydroxide, sodium hydroxide, lithium hydroxide, potassium hydroxide, cesium hydroxide, rubidium hydroxide, and any combinations thereof. In one or more embodiments, the organic base is a quaternary ammonium hydroxide (e.g., an alkylammonium hydroxide such as a tetraalkylammonium hydroxide) or a quaternary phosphonium hydroxide (e.g., an alkylphosphonium hydroxide such as a tetraalkylphosphonium hydroxide). In one or more embodiments, the quaternary ammonium hydroxide is selected from the group consisting of tetrabutylammonium hydroxide, ethyltrimethylammonium hydroxide, tetrapropylammonium hydroxide, tetraethylammonium hydroxide, tetramethylammonium hydroxide, diethyldimethylammonium hydroxide, dimethyldipropylammonium hydroxide, benzyltrimethylammonium hydroxide, tris(2-hydroxyethyl)methylammonium hydroxide, and any combinations thereof. In one or more embodiments, the quaternary phosphonium hydroxide is selected from the group consisting of tetramethylphosphonium hydroxide, tetraethylphosphonium hydroxide, tetrapropylphosphonium hydroxide, tetrabutylphosphonium hydroxide, tetrapentylphosphonium hydroxide, triethylmethylphosphonium hydroxide, tetrakis(hydroxymethyl)phosphonium hydroxide, tetraphenylphosphonium hydroxide, and any combinations thereof. In one or more embodiments, the quaternary ammonium hydroxide or quaternary phosphonium hydroxide does not include covalently bound hydroxyl groups (e.g., does not include choline hydroxide or tris(2-hydroxyethyl)methylammonium hydroxide).

In one or more embodiments, the pH adjuster is an acid selected from the group consisting of gluconic acid, lactic acid, citric acid, tartaric acid, malic acid, glycolic acid, malonic acid, formic acid, oxalic acid, acetic acid, propionic acid, peracetic acid, succinic acid, amino acetic acid, phenoxyacetic acid, bicine, diglycolic acid, glyceric acid, tricine, alanine, histidine, valine, isoleucine, leucine, methionine, phenylalanine, cysteine, selenocysteine, glycine, proline, serine, threonine, asparagine, glutamine, aspartic acid, glutamic acid, arginine, histidine, lysine, tyrosine, tryptophan, benzoic acid, 1,2-ethanedisulfonic acid, 4-amino-3-hydroxy-1-naphthalenesulfonic acid, 8-hydroxyquinoline-5-sulfonic acid, aminomethanesulfonic acid, benzenesulfonic acid, hydroxylamine O-sulfonic acid, methanesulfonic acid, m-xylene-4-sulfonic acid, poly(4-styrenesulfonic acid), polyanetholesulfonic acid, p-toluenesulfonic acid, trifluoromethane-sulfonic acid, ethyl phosphoric acid, cyanoethyl phosphoric acid, phenyl phosphoric acid, vinyl phosphoric acid, poly(vinylphosphonic acid), 1-hydroxyethane-1,1-diphosphonic acid, nitrilotri(methylphosphonic acid), diethylenetriaminepentakis (methylphosphonic acid), N,N,N′,N′-ethylenediaminetetrakis(methylene phosphonic acid), n-hexylphosphonic acid, benzylphosphonic acid, phenylphosphonic acid, salts thereof, and mixtures thereof.

In one or more embodiments, the at least one pH adjuster is in an amount from about 0.001% to 10% by weight of the polishing composition. For example, the at least one pH adjuster can be at least about 0.001% (e.g., at least about 0.005%, at least about 0.01%, at least about 0.05%, at least about 0.1%, at least about 0.5%, at least about 1%, at least about 2.5%, or at least about 3%) by weight to at most about 10% (e.g., at most about 7.5%, at most about 5%, at most about 2.5%, or at most about 1%) by weight of the polishing composition described herein.

Without wishing to be bound by theory, the inventors surprisingly discovered that the use of pH adjusters to keep the pH of the polishing composition acidic can reduce corrosion of the tungsten surfaces that may be present during polishing.

In one or more embodiments, the polishing composition described herein includes at least one guanamine (e.g., two or three) compound, wherein the guanamine compound includes a structure of formula (I):

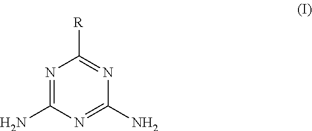

or a salt thereof,
where R is a group that comprises an optionally substituted aliphatic, optionally substituted aromatic, or optionally substituted heterocyclic, or optionally substituted aromatic-aliphatic. In one or more embodiments, R is optionally substituted alkyl, optionally substituted aryl, optionally substituted aromatic, optionally substituted triazinyl, or optionally substituted arylalkyl. In one or more embodiments, the polishing composition described herein can include a single guanamine compound according to formula (I). In one or more embodiments, R in formula (I) is a substituted or unsubstituted C₁-C₂₀ alkyl group, a substituted or unsubstituted C₂-C₂₀ alkenyl group, a substituted or unsubstituted cycloalkyl group, or a substituted or unsubstituted aryl group. In one or more embodiments, the guanamine compound includes a structure of formula (IA):

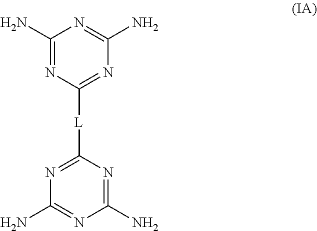

or a salt thereof,
where L is a linker (e.g., optionally substituted aliphatic, optionally substituted heteroaliphatic, or a combination thereof, as well as any described herein). In one or more embodiments, L is

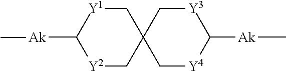

or -Ak-; each Ak is, independently, a covalent bond, optionally substituted aliphatic (e.g., optionally substituted alkylene), or optionally substituted heteroaliphatic (e.g., optionally substituted heteroalkylene); and each of Y¹, Y², Y³, and Y⁴ is, independently, alkylene (e.g., —CR^{C1}R^{C2}—, in which each of R^{C1} and R^{C2} is, independently, hydrogen, aliphatic, heteroaliphatic, aromatic, as defined herein, or any combination thereof), oxy (—O—), thio (—S—), or imino (—NR^{N1}—, in which R^{N1} is hydrogen, aliphatic, heteroaliphatic, aromatic, as defined herein, or any combination thereof). In one or more embodiments, the at least one guanamine may be a bisguanamine. In one or more embodiments, the at least one guanamine is selected from the group consisting of butyroguanamine, acetoguanamine, benzoguanamine, caprinoguanamine, adipoguanamine, stearoguanamine, 2,4-diamine-6-nonyl-1,3,5-triazine, 2,4-diamino-6-undecyl-1,3,5-triazine, 3,9-bis[2-(3,5-diamino-2,4,6-triazaphenyl)ethyl]-2,4,8,10-tetraoxaspiro[5.5]undecane, 2,4-diamino-6-butylamino-1,3,5-triazine, 2,4-diamino-6-(4-methylphenyl)-1,3,5-triazine, 2,4-diamino-6-[2-(2-methyl-1-imidazolyl)ethyl]-1,3,5-triazine, 2,4-diamino-6-[2-(2-undecyl-1-imidazolyl)ethyl]-1,3,5-triazine, or mixtures thereof. Without wishing to be bound by theory, the inventors surprisingly discovered that the guanamine compound can be highly effective at reducing corrosion of certain materials (e.g., W/Mo) in a semiconductor substrate when the substrate is polished by the polishing composition described herein.

By “aliphatic” is meant a hydrocarbon group having at least one carbon atom to 50 carbon atoms (C₁₋₅₀). For example, the hydrocarbon group can have at least one carbon atom (C₁) (e.g., at least 2 carbon atoms (C₂), at least 3 carbon atoms (C₃), at least 4 carbon atoms (C₄), at least 5 carbon atoms (C₅), at least 6 carbon atoms (C₆), at least 7 carbon atoms (C₇), at least 8 carbon atoms (C₈), at least 10 carbon atoms (C₁₀), at least 12 carbon atoms (C₁₂), at least 14 carbon atoms (C₁₄), at least 16 carbon atoms (C₁₆), at least 18 carbon atoms (C₁₈), or at least 20 carbon atoms (C₂₀)) and/or at most 50 carbon atoms (C₅₀) (e.g., at most 49 carbon atoms (C₄₉), at most 48 carbon atoms (C₄₈), at most 47 carbon atoms (C₄₇), at most 46 carbon atoms (C₄₆), at most 45 carbon atoms (C₄₅), at most 44 carbon atoms (C₄₄), at most 43 carbon atoms (C₄₃), at most 42 carbon atoms (C₄₂), at most 41 carbon atoms (C₄₁), at most 40 carbon atoms (C₄₀), at most 38 carbon atoms (C₃₈), at most 36 carbon atoms (C₃₆), at most 34 carbon atoms (C₃₄), at most 32 carbon atoms (C₃₂), at most 30 carbon atoms (C₃₀), at most 28 carbon atoms (C₂₈), at most 26 carbon atoms (C₂₆), at most 24 carbon atoms (C₂₄), at most 22 carbon atoms (C₂₂), at most 20 carbon atoms (C₂₀), at most 18 carbon atoms (C₁₈), at most 16 carbon atoms (C₁₆), at most 14 carbon atoms (C₁₄), at most 12 carbon atoms (C₁₂), at most 10 carbon atoms (C₁₀), at most 9 carbon atoms (C₉), at most 8 carbon atoms (C₈), at most 7 carbon atoms (C₇), at most 6 carbon atoms (C₆), at most 5 carbon atoms (C₅), at most 4 carbon atoms (C₄), or at most 3 carbon atoms (C₃). The aliphatic group can include alkanes (or alkyl), alkenes (or alkenyl), alkynes (or alkynyl), including cyclic versions thereof, and further including straight- and branched-chain arrangements, and all stereo and position isomers as well. The aliphatic group can also be unsubstituted or substituted (e.g. with one or more substituents described herein for alkyl). The aliphatic group can be monovalent or multivalent (e.g., bivalent by removing one or more hydrogens to form appropriate attachment to the parent molecular group, which can include monovalent or multivalent forms of alkanes (or alkyl or alkylene), alkenes (or alkenyl or alkenylene), alkynes (or alkynyl or alkynylene).

By “alkenyl” is meant an unsaturated monovalent hydrocarbon group having at least two carbon atom to 50 carbon atoms (C₂₋₅₀) and at least one carbon-carbon double bond, in which the unsaturated monovalent hydrocarbon group can be derived from removing one hydrogen atom from one carbon atom of a parent alkene. For example, the unsaturated monovalent hydrocarbon group can have at least 2 carbon atoms (C₂) (e.g., at least 3 carbon atoms (C₃), at least 4 carbon atoms (C₄), at least 5 carbon atoms (C₅), at least 6 carbon atoms (C₆), at least 7 carbon atoms (C₇), at least 8 carbon atoms (C₈), at least 10 carbon atoms (C₁₀), at least 12 carbon atoms (C₁₂), at least 14 carbon atoms (C₁₄), at least 16 carbon atoms (C₁₆), at least 18 carbon atoms (C₁₈), or at least 20 carbon atoms (C₂₀)) and/or at most 50 carbon atoms (C₅₀) (e.g., at most 49 carbon atoms (C₄₉), at most 48 carbon atoms (C₄₈), at most 47 carbon atoms (C₄₇), at most 46 carbon atoms (C₄₆), at most 45 carbon atoms (C₄₅), at most 44 carbon atoms (C₄₄), at most 43 carbon atoms (C₄₃), at most 42 carbon atoms (C₄₂), at most 41 carbon atoms (C₄₁), at most 40 carbon atoms (C₄₀), at most 38 carbon atoms (C₃₈), at most 36 carbon atoms (C₃₆), at most 34 carbon atoms (C₃₄), at most 32 carbon atoms (C₃₂), at most 30 carbon atoms (C₃₀), at most 28 carbon atoms (C₂₈), at most 26 carbon atoms (C₂₆), at most 24 carbon atoms (C₂₄), at most 22 carbon atoms (C₂₂), at most 20 carbon atoms (C₂₀), at most 18 carbon atoms (C₁₈), at most 16 carbon atoms (C₁₆), at most 14 carbon atoms (C₁₄), at most 12 carbon atoms (C₁₂), at most 10 carbon atoms (C₁₀), at most 9 carbon atoms (C₉), at most 8 carbon atoms (C₈), at most 7 carbon atoms (C₇), at most 6 carbon atoms (C₆), at most 5 carbon atoms (C₅), at most 4 carbon atoms (C₄), or at most 3 carbon atoms (C₃). An alkenyl group can be branched, straight-chain, cyclic (e.g., cycloalkenyl), cis, or trans (e.g. E or Z). An example of an alkenyl includes an optionally substituted C₂₋₂₄ alkyl group having one or more double bonds. The alkenyl group can be monovalent or multivalent (e.g., bivalent) by removing one or more hydrogens to form appropriate attachment to the parent molecular group. The alkenyl group can also be unsubstituted or substituted (e.g., with one or more substituents described herein for alkyl).

By “alkyl” is meant a saturated monovalent hydrocarbon group having at least one carbon atom to 50 carbon atoms (C₁₋₅₀), in which the saturated monovalent hydrocarbon group can be derived from removing one hydrogen atom from one carbon atom of a parent compound (e.g., alkane). For example, the saturated monovalent hydrocarbon group can have at least one carbon atom (C₁) (e.g., at least 2 carbon atoms (C₂), at least 3 carbon atoms (C₃), at least 4 carbon atoms (C₄), at least 5 carbon atoms (C₅), at least 6 carbon atoms (C₆), at least 7 carbon atoms (C₇), at least 8 carbon atoms (C₈), at least 10 carbon atoms (C₁₀), at least 12 carbon atoms (C₁₂), at least 14 carbon atoms (C₁₄), at least 16 carbon atoms (C₁₆), at least 18 carbon atoms (C₁₈), or at least 20 carbon atoms (C₂₀)) and/or at most 50 carbon atoms (C₅₀) (e.g., at most 49 carbon atoms (C₄₉), at most 48 carbon atoms (C₄₈), at most 47 carbon atoms (C₄₇), at most 46 carbon atoms (C₄₆), at most 45 carbon atoms (C₄₅), at most 44 carbon atoms (C₄₄), at most 43 carbon atoms (C₄₃), at most 42 carbon atoms (C₄₂), at most 41 carbon atoms (C₄₁), at most 40 carbon atoms (C₄₀), at most 38 carbon atoms (C₃₈), at most 36 carbon atoms (C₃₆), at most 34 carbon atoms (C₃₄), at most 32 carbon atoms (C₃₂), at most 30 carbon atoms (C₃₀), at most 28 carbon atoms (C₂₈), at most 26 carbon atoms (C₂₆), at most 24 carbon atoms (C₂₄), at most 22 carbon atoms (C₂₂), at most 20 carbon atoms (C₂₀), at most 18 carbon atoms (C₁₈), at most 16 carbon atoms (C₁₆), at most 14 carbon atoms (C₁₄), at most 12 carbon atoms (C₁₂), at most 10 carbon atoms (C₁₀), at most 9 carbon atoms (C₉), at most 8 carbon atoms (C₈), at most 7 carbon atoms (C₇), at most 6 carbon atoms (C₆), at most 5 carbon atoms (C₅), at most 4 carbon atoms (C₄), or at most 3 carbon atoms (C₃). An alkyl group can be branched, straight-chain, or cyclic (e.g., cycloalkyl). An example of an alkyl includes a branched or unbranched saturated hydrocarbon group of 1 to 24 carbon atoms, such as methyl, ethyl, n-propyl, isopropyl, n-butyl, isobutyl, s-butyl, t-butyl, n-pentyl, isopentyl, s-pentyl, neopentyl, hexyl, heptyl, octyl, nonyl, decyl, dodecyl, tetradecyl, hexadecyl, eicosyl, tetracosyl, and the like. The alkyl group can be monovalent or multivalent (e.g., bivalent) by removing one or more hydrogens to form appropriate attachment to the parent molecular group. The alkyl group can also be unsubstituted or substituted. For example, the alkyl group can be substituted with one, two, three or, in the case of alkyl groups of two carbons or more, four substituents independently selected from the group consisting of: (1) alkoxy (e.g., —O—R, in which R is alkyl, such as C₁₋₆ alkyl); (2) amino (e.g., —NR¹R², where each of R¹ and R² is, independently, selected from hydrogen, aliphatic, heteroaliphatic, aromatic, as defined herein, or any combination thereof, or R¹ and R², taken together with the nitrogen atom to which each are attached, can form a heterocyclyl group, as defined herein); (3) amido (e.g., —C(O)NR¹R² or —NHCOR¹, where each of R¹ and R² is, independently, selected from hydrogen, aliphatic, heteroaliphatic, aromatic, as defined herein, or any combination thereof, or R¹ and R², taken together with the nitrogen atom to which each are attached, can form a heterocyclyl group, as defined herein); (4) aryl; (5) alkyl; (6) arylalkoxy (e.g., —O-L-R, in which L is alkyl and R is aryl); (7) aryloyl (e.g., —C(O)—R, in which R is aryl); (8) azido (e.g., —N₃); (9) cyano (e.g., —CN); (10) aldehyde (e.g., —C(O)H); (11) C₃₋₈ cycloalkyl; (12) halo (e.g., F, Cl, Br, or I); (13) heterocyclyl (e.g., as defined herein, such as a 5-, 6- or 7-membered ring containing one, two, three, or four non-carbon heteroatoms); (14) heterocyclyloxy (e.g., —O—R, in which R is heterocyclyl, as defined herein); (15) heterocyclyloyl (e.g., —C(O)—R, in which R is heterocyclyl, as defined herein); (16) hydroxyl (e.g., —OH); (17) nitro (e.g., —NO₂); (18) oxo (e.g., ═O); (19) —CO₂R¹, where R¹ is selected from hydrogen, aliphatic, heteroaliphatic, aromatic, as defined herein, or any combination thereof; (20) —C(O)NR¹R², where each of R¹ and R² is, independently, selected from hydrogen, aliphatic, heteroaliphatic, aromatic, as defined herein, or any combination thereof; (21) —SO₂R¹, where R¹ is selected from hydrogen, aliphatic, heteroaliphatic, aromatic, as defined herein, or any combination thereof; and (22) —SO₂NR¹R², where each of R¹ and R² is, independently, selected from hydrogen, aliphatic, heteroaliphatic, aromatic, as defined herein, or any combination thereof. The alkyl group can be a primary, secondary, or tertiary alkyl group substituted with one or more substituents (e.g., one or more halo or alkoxy). In some embodiments, the unsubstituted alkyl group is a C₁₋₃, C₁₋₆, C₁₋₁₂, C₁₋₁₆, C₁₋₁₈, C₁₋₂₀, or C₁₋₂₄ alkyl group.

By “aromatic” is meant a cyclic, conjugated group or moiety of, unless specified otherwise, from 5 to 15 ring atoms having a single ring (e.g., phenyl) or multiple condensed rings in which at least one ring is aromatic (e.g., naphthyl, indolyl, or pyrazolopyridinyl); that is, at least one ring, and optionally multiple condensed rings, have a continuous, delocalized π-electron system. For example, the cyclic, conjugated group or moiety can have at least 5 ring atoms (e.g., at least 6 ring atoms, at least 7 ring atoms, at least 8 ring atoms, at least 9 ring atoms, or at least 10 ring atoms) and/or at most 15 ring atoms (e.g., at most 14 ring atoms, at most 13 ring atoms, at most 12 ring atoms, at most 11 ring atoms, or at most 10 ring atoms). Typically, the number of out of plane π-electrons corresponds to the Huckel rule (4n+2). The point of attachment to the parent structure typically is through an aromatic portion of the condensed ring system. The aromatic group can include one or more heteroatoms (e.g., including but not limited to oxygen, nitrogen, sulfur, silicon, boron, selenium, phosphorous, and oxidized forms thereof within the group, such as in a heteroaromatic group). The aromatic group can also be unsubstituted or substituted (e.g., with one or more substituents described herein for alkyl). The aromatic group can be monovalent or multivalent (e.g., bivalent) by removing one or more hydrogens to form appropriate attachment to the parent molecular group, which can include monovalent or multivalent forms of aromatics (or aryl or arylene) or heteroaromatics (or heteroaryl or heteroarylene).

By “aromatic-aliphatic” is meant an aromatic group that is or can be coupled to a compound disclosed herein, wherein the aromatic group is or becomes coupled through an aliphatic group, as defined herein. In some embodiments, the aromatic-aliphatic group is -L-R, in which L is an aliphatic group, as defined herein, and R is an aromatic group, as defined herein. In some embodiments, the aromatic-aliphatic group is -L-R, in which L is an alkylene group, as defined herein, and R is an aryl group, as defined herein.

By “aryl” is meant an aromatic carbocyclic group comprising at least five carbon atoms to 15 carbon atoms (C₅₋₁₅) and having a single ring or multiple condensed rings. For example, the aromatic carbocyclic group can have at least 5 carbon atoms (C₅) (e.g., at least 6 carbon atoms (C₆), at least 7 carbon atoms (C₇), at least 8 carbon atoms (C₈), at least 9 carbon atoms (C₉), or at least 10 carbon atoms (C₁₀)) and/or at most 15 carbon atoms (C₁₅) (e.g., at most 14 carbon atoms (C₁₁), at most 13 carbon atoms (C₁₃), at most 12 carbon atoms (C₁₂), at most 11 carbon atoms (C₁₁), or at most 10 carbon atoms (C₁₀)). Examples of aryl groups include, but are not limited to, benzyl, naphthalene, phenyl, biphenyl, phenoxybenzene, and the like. The term aryl also includes heteroaryl, which is defined as a group that contains an aromatic group that has at least one heteroatom incorporated within the ring of the aromatic group. Examples of heteroatoms include, but are not limited to, nitrogen, oxygen, sulfur, and phosphorus. Likewise, the term non-heteroaryl, which is also included in the term aryl, defines a group that contains an aromatic group that does not contain a heteroatom. The aryl group can be unsubstituted or substituted (e.g., with one or more substituents described herein for alkyl). The aryl group can be monovalent or multivalent (e.g., bivalent) by removing one or more hydrogens to form appropriate attachment to the parent molecular group.

By “cycloalkyl” is meant a monovalent saturated or unsaturated non-aromatic cyclic hydrocarbon group of from three to eight carbons, unless otherwise specified, and is exemplified by cyclopropyl, cyclobutyl, cyclopentyl, cyclohexyl, cycloheptyl, bicyclo[2.2.1.heptyl], and the like. The cycloalkyl group can also be unsubstituted or substituted (e.g., with one or more substituents described herein for alkyl).

By “heteroaliphatic” is meant an aliphatic group, as defined herein, including at least one heteroatom to 20 heteroatoms, which can be selected from, but not limited to oxygen, nitrogen, sulfur, silicon, boron, selenium, phosphorous, and oxidized forms thereof within the group. For example, the aliphatic group can have at least one heteroatom (e.g., at least 2 heteroatoms, at least 3 heteroatoms, at least 4 heteroatoms, at least 5 heteroatoms, at least 6 heteroatoms, at least 7 heteroatoms, at least 8 heteroatoms, at least 9 heteroatoms, at least 10 heteroatoms, at least 11 heteroatoms, or at least 12 heteroatoms) and/or at most 20 heteroatoms (e.g., at most 19 heteroatoms, at most 18 heteroatoms, at most 17 heteroatoms, at most 16 heteroatoms, at most 15 heteroatoms, at most 14 heteroatoms, at most 13 heteroatoms, at most 12 heteroatoms, at most 11 heteroatoms, at most 10 heteroatoms, at most 9 heteroatoms, at most 8 heteroatoms, at most 7 heteroatoms, at most 6 heteroatoms, at most 5 heteroatoms, at most 4 heteroatoms, or at most 3 heteroatoms).

By “heterocyclic” or “heterocyclyl” is meant a 5-, 6- or 7-membered ring, unless otherwise specified, containing one, two, three, or four non-carbon heteroatoms (e.g., independently selected from the group consisting of nitrogen, oxygen, phosphorous, sulfur, or halo). The 5-membered ring has zero to two double bonds and the 6- and 7-membered rings have zero to three double bonds. The term “heterocyclyl” also includes bicyclic, tricyclic and tetracyclic groups in which any of the above heterocyclic rings is fused to one, two, or three rings independently selected from the group consisting of an aryl ring, a cyclohexane ring, a cyclohexene ring, a cyclopentane ring, a cyclopentene ring, and another monocyclic heterocyclic ring, such as indolyl, quinolyl, isoquinolyl, tetrahydroquinolyl, benzofuryl, benzothienyl and the like. Heterocyclics include thiiranyl, thietanyl, tetrahydrothienyl, thianyl, thiepanyl, aziridinyl, azetidinyl, pyrrolidinyl, piperidinyl, azepanyl, pyrrolyl, pyrrolinyl, pyrazolyl, pyrazolinyl, pyrazolidinyl, imidazolyl, imidazolinyl, imidazolidinyl, pyridyl, homopiperidinyl, pyrazinyl, piperazinyl, pyrimidinyl, pyridazinyl, oxazolyl, oxazolidinyl, oxazolidonyl, isoxazolyl, isoxazolidiniyl, morpholinyl, thiomorpholinyl, thiazolyl, thiazolidinyl, isothiazolyl, isothiazolidinyl, indolyl, quinolinyl, isoquinolinyl, benzimidazolyl, benzothiazolyl, benzoxazolyl, furyl, thienyl, thiazolidinyl, isothiazolyl, isoindazoyl, triazolyl, tetrazolyl, oxadiazolyl, uricyl, thiadiazolyl, pyrimidyl, tetrahydrofuranyl, dihydrofuranyl, dihydrothienyl, dihydroindolyl, tetrahydroquinolyl, tetrahydroisoquinolyl, pyranyl, dihydropyranyl, tetrahydropyranyl, dithiazolyl, dioxanyl, dioxinyl, dithianyl, trithianyl, oxazinyl, thiazinyl, oxothiolanyl, triazinyl, benzofuranyl, benzothienyl, and the like. The heterocyclyl group can be unsubstituted or substituted (e.g., with one or more substituents described herein for alkyl). The heterocyclyl group can be monovalent or multivalent (e.g., bivalent) by removing one or more hydrogens to form appropriate attachment to the parent molecular group.

Linkers can include a bond (e.g., a covalent bond); an optionally substituted alkylene; an optionally substituted heteroalkylene (e.g., poly(ethylene glycol), such as —(OCH₂CH₂)ₙ—, in which n is an integer of 1 to 100); an optionally substituted arylene; or an optionally substituted heteroarylene. An alkylene can include a multivalent (e.g., bivalent, trivalent, tetravalent, etc.) form of an alkyl group. Examples of alkylene groups include methylene, ethylene, propylene, butylene, etc. For example, the alkylene group can have at least one carbon atom (C₁) (e.g., at least 2 carbon atoms (C₂), at least 3 carbon atoms (C₃), at least 4 carbon atoms (C₄), at least 5 carbon atoms (C₅), at least 6 carbon atoms (C₆), at least 7 carbon atoms (C₇), at least 8 carbon atoms (C₈), at least 10 carbon atoms (C₁₀), at least 12 carbon atoms (C₁₂), at least 14 carbon atoms (C₁₄), at least 16 carbon atoms (C₁₆), at least 18 carbon atoms (C₁₈), or at least 20 carbon atoms (C₂₀)) and/or at most 50 carbon atoms (C₅₀) (e.g., at most 49 carbon atoms (C₄₉), at most 48 carbon atoms (C₄₈), at most 47 carbon atoms (C₄₇), at most 46 carbon atoms (C₄₆), at most 45 carbon atoms (C₄₅), at most 44 carbon atoms (C₄₄), at most 43 carbon atoms (C₄₃), at most 42 carbon atoms (C₄₂), at most 41 carbon atoms (C₄₁), at most 40 carbon atoms (C₄₀), at most 38 carbon atoms (C₃₈), at most 36 carbon atoms (C₃₆), at most 34 carbon atoms (C₃₄), at most 32 carbon atoms (C₃₂), at most 30 carbon atoms (C₃₀), at most 28 carbon atoms (C₂₈), at most 26 carbon atoms (C₂₆), at most 24 carbon atoms (C₂₄), at most 22 carbon atoms (C₂₂), at most 20 carbon atoms (C₂₀), at most 18 carbon atoms (C₁₈), at most 16 carbon atoms (C₁₆), at most 14 carbon atoms (C₁₄), at most 12 carbon atoms (C₁₂), at most 10 carbon atoms (C₁₀), at most 9 carbon atoms (C₉), at most 8 carbon atoms (C₈), at most 7 carbon atoms (C₇), at most 6 carbon atoms (C₆), at most 5 carbon atoms (C₅), at most 4 carbon atoms (C₄), or at most 3 carbon atoms (C₃). The alkylene group can be branched or unbranched. The alkylene group can also be unsubstituted or substituted (e.g., with one or more substituents described herein for alkyl). A heteroalkylene can be an alkylene group containing one, two, three, or four non-carbon heteroatoms (e.g., independently selected from the group consisting of nitrogen, oxygen, phosphorous, sulfur, or halo).

By “salt” is meant an ionic form of a compound or structure (e.g., any formulas, compounds, or compositions described herein), which includes a cation or anion compound to form an electrically neutral compound or structure. For example, non-toxic salts are described in Berge S. M. et al., “Pharmaceutical salts,” J. Pharm. Sci. 1977 January; 66(1):1-19; and in “Handbook of Pharmaceutical Salts: Properties, Selection, and Use,” Wiley-VCH, April 2011 (2nd rev. ed., eds. P. H. Stahl and C. G. Wermuth. The salts can be prepared in situ during the final isolation and purification of the compounds of the invention or separately by reacting the free base group with a suitable organic acid (thereby producing an anionic salt) or by reacting the acid group with a suitable metal or organic salt (thereby producing a cationic salt). Salts can include anionic salts (e.g., halide salts, carbonate salts, sulfate salts, sulfonate salts, phosphate salts, phosphonate salts, and the like) and cationic salts (e.g., metal salts, such as alkali or alkaline earth salts, e.g., barium, calcium lithium, magnesium, potassium, sodium, and the like; other metal salts, such as aluminum, bismuth, iron, and zinc; as well as nontoxic ammonium, quaternary ammonium, and amine cations).

In one or more embodiments, the guanamine compound is included in a polishing composition described herein in an amount from at least about 0.1 ppm (e.g., at least about 0.5 ppm, at least about 1 ppm, at least about 5 ppm, at least about 10 ppm, at least about 25 ppm, at least about 50 ppm, at least about 75 ppm, or at least about 100 ppm) to at most about 1000 ppm (e.g., at most about 900 ppm, at most about 800 ppm, at most about 700 ppm, at most about 600 ppm, at most about 500 ppm, or at most about 250 ppm) based on the total weight of the composition.

In one or more embodiments, the polishing compositions described herein can optionally include at least one (e.g., two or three) amino acid or poly(amino acid). In one or more embodiments, the compositions described herein can optionally include a single amino acid or poly(amino acid). In one or more embodiments, the amino acid is chemically distinct from the pH adjuster. In one or more embodiments, the amino acid is selected from the group consisting of alanine, histidine, valine, phenylalanine, proline, glutamine, aspartic acid, glutamic acid, arginine, lysine, tyrosine, and mixtures thereof. In one or more embodiments, the poly(amino acid) is selected from the group consisting of poly-DL-alanine, poly-L-arginine hydrochloride, poly-(α,β)-DL-aspartic acid sodium salt, poly-7-benzyl-L-glutamate, poly-ε-Cbz-L-lysine, poly(T-ethyl-L-glutamate), poly-D-glutamic acid sodium salt, poly-L-glutamic acid sodium salt, polyglycine, poly-L-histidine, poly(L-lactide), poly-D-lysine hydrobromide, poly-L-lysine hydrobromide, poly-DL-lysine hydrobromide, poly-L-ornithine hydrobromide, poly-DL-ornithine hydrobromide, poly-L-proline, poly-L-threonine, and mixtures thereof. Without wishing to be bound by theory, it is believed that an amino acid or poly(amino acid) (such as those described above) can function as an optional, additional metal corrosion inhibitor that further reduces the removal rate and/or static etch rate of metals (e.g., tungsten and/or molybdenum) in a semiconductor substrate.

In one or more embodiments, the at least one amino acid is in an amount from about 0.0001% to 1% by weight of the polishing composition. For example, the at least one amino acid can be at least about 0.0001% (e.g., at least about 0.0005%, at least about 0.001%, at least about 0.005%, at least about 0.01%, at least about 0.05%, at least about 0.1%, or at least about 0.5%) by weight to at most about 1% (e.g., at most about 0.5%, at most about 0.25%, at most about 0.1%, or at most about 0.05%) by weight of the polishing composition described herein.

In one or more embodiments, the at least one (e.g., two or three distinct) nitride inhibiting compound includes a hydrophobic portion containing a C₄ to C₄₀ hydrocarbon group (e.g., containing an alkyl group and/or an alkenyl group); and a hydrophilic portion containing at least one group selected from the group consisting of a sulfinate group, a sulfate group, a sulfonate group, a carboxylate group, a phosphate group, and a phosphonate group (e.g., including protonated forms thereof). In one or more embodiments, the hydrophobic portion and the hydrophilic portion are separated by zero to ten (e.g., 1, 2, 3, 4, 5, 6, 7, 8, or 9) alkylene oxide groups (e.g., —(CH₂)ₙO— groups in which n can be 1, 2, 3, or 4). In one or more embodiments, the nitride inhibiting compound has zero alkylene oxide groups separating the hydrophobic portion and the hydrophilic portion. Without wishing to be bound by theory, it is believed that the presence of alkylene oxide groups within the nitride inhibiting compound may not be preferred in some embodiments as they may create slurry stability issues and increase silicon nitride removal rate.

In one or more embodiments, the nitride inhibiting compound has a hydrophobic portion containing a hydrocarbon group that includes at least 4 carbon atoms (C₄) (e.g., at least 6 carbon atoms (C₆), at least 8 carbon atoms (C₈), at least 10 carbon atoms (C₁₀), at least 12 carbon atoms (C₁₂), at least 14 carbon atoms (C₁₄), at least 16 carbon atoms (C₁₆), at least 18 carbon atoms (C₁₈), at least 20 carbon atoms (C₂₀), or at least 22 carbon atoms (C₂₂)) and/or at most 40 carbon atoms (C₄₀) (e.g., at most 38 carbon atoms (C₃₈), at most 36 carbon atoms (C₃₆), at most 34 carbon atoms (C₃₄), at most 32 carbon atoms (C₃₂), at most 30 carbon atoms (C₃₀), at most 28 carbon atoms (C₂₈), at most 26 carbon atoms (C₂₆), at most 24 carbon atoms (C₂₄), or at most 22 carbon atoms (C₂₂)). The hydrocarbon groups mentioned herein refer to groups that contain only carbon and hydrogen atoms and can include both saturated groups (e.g., linear, branched, or cyclic alkyl groups) and unsaturated groups (e.g., linear, branched, or cyclic alkenyl groups; linear, branched, or cyclic alkynyl groups; or aromatic groups (e.g., phenyl or naphthyl)). In one or more embodiments, the hydrophilic portion of the nitride inhibiting compound contains at least one group selected from a phosphate group and a phosphonate group (e.g., including protonated forms thereof). It is to be noted that the term “phosphonate group” is expressly intended to include phosphonic acid groups, which can include protonated or deprotonated forms.

In one or more embodiments, the nitride inhibiting compound is selected from the group consisting of naphthalenesulfonic acid-formalin condensate, lauryl phosphate, myristyl phosphate, stearyl phosphate, octadecylphosphonic acid, oleyl phosphate, behenyl phosphate, octadecyl phosphate, lacceryl phosphate, oleth-3-phosphate, and oleth-10-phosphate.

In one or more embodiments, the nitride inhibiting compound is included in a polishing composition described herein in an amount from at least about 0.1 ppm (e.g., at least about 0.5 ppm, at least about 1 ppm, at least about 5 ppm, at least about 10 ppm, at least about 25 ppm, at least about 50 ppm, at least about 75 ppm, or at least about 100 ppm) to at most about 1000 ppm (e.g., at most about 900 ppm, at most about 800 ppm, at most about 700 ppm, at most about 600 ppm, at most about 500 ppm, or at most about 250 ppm) based on the total weight of the composition.

In one or more embodiments, the pH value of the polishing composition can range from at least about 2 (e.g., at least about 2.5, at least about 3, at least about 3.5, at least about 4, at least about 4.5, at least about 5, at least about 5.5, at least about 6, or at least about 6.5) to at most about 14 (e.g., at most about 13.5, at most about 13, at most about 12.5, at most about 12, at most about 11.5, at most about 11, at most about 10.5, at most about 10, at most about 9.5, at most about 9, at most about 8.5, at most about 8, at most about 7.5, at most about 7, at most about 6.5, at most about 6, at most about 5.5, at most about 5, at most about 4.5, at most about 4, at most about 3.5, or at most about 3). Without wishing to be bound by theory, it is believed that a polishing composition having a pH lower than 2 would significantly increase corrosion and particle residues. However, in some embodiments, a polishing composition having a pH higher than 7 can lead to reduced solubility of the guanamine compound in solution and increased tungsten surface corrosion thus a pH of 7 or less may be preferred in some instances. To obtain the desired pH, the relative concentrations of the ingredients in the polishing compositions described herein can be adjusted.

In one or more embodiments, the polishing composition described herein can optionally include at least one (e.g., two or three) azole-containing corrosion inhibitor. In one or more embodiments, the polishing composition can include a single azole-containing corrosion inhibitor. In some embodiments, the at least one azole-containing corrosion inhibitor is selected from the group consisting of substituted or unsubstituted triazoles, substituted or unsubstituted tetrazoles, substituted or unsubstituted benzotriazoles, substituted or unsubstituted pyrazoles, substituted or unsubstituted imidazoles, substituted or unsubstituted benzimidazoles, substituted or unsubstituted thiadiazoles, substituted or unsubstituted thiabendazole, substituted or unsubstituted adenines, substituted or unsubstituted xanthines, and substituted or unsubstituted guanines. In one or more embodiments, the azole-containing corrosion inhibitor can be selected from the group consisting of 1,2,4-triazole, 1,2,3-triazole, tetrazole, benzotriazole, tolyltriazole, methyl benzotriazole (e.g., 1-methyl benzotriazole, 4-methyl benzotriazole, or 5-methyl benzotriazole), ethyl benzotriazole (e.g., 1-ethyl benzotriazole), propyl benzotriazole (e.g., 1-propyl benzotriazole), butyl benzotriazole (e.g., 1-butyl benzotriazole or 5-butyl benzotriazole), pentyl benzotriazole (e.g., 1-pentyl benzotriazole), hexyl benzotriazole (e.g., 1-hexyl benzotriazole or 5-hexyl benzotriazole), dimethyl benzotriazole (e.g., 5,6-dimethyl benzotriazole), chloro benzotriazole (e.g., 5-chloro benzotriazole), dichloro benzotriazole (e.g., 5,6-dichloro benzotriazole), chloromethyl benzotriazole (e.g., 1-(chloromethyl)-1-H-benzotriazole), chloroethyl benzotriazole, phenyl benzotriazole, benzyl benzotriazole, aminotriazole, aminobenzimidazole, aminotetrazole, pyrazole, imidazole, adenine, xanthine, guanine, benzimidazole, thiabendazole, 1-hydroxybenzotriazole, 2-methylbenzothiazole, 2-aminobenzimidazole, 2-amino-5-ethyl-1,3,4-thiadiazole, 3,5-diamino-1,2,4-triazole, 3-amino-5-methylpyrazole, 4-amino-4H-1,2,4-triazole, and mixtures thereof. Without wishing to be bound by theory, it is believed that an azole-containing corrosion inhibitor (such as those described above) can significantly reduce or minimize the removal rate of metals (e.g., copper) in a semiconductor substrate.

In some embodiments, the at least one azole-containing corrosion inhibitor is in an amount of from at least about 0.0001% (e.g., at least about 0.0002%, at least about 0.0005%, at least about 0.001%, at least about 0.002%, at least about 0.005%, at least about 0.01%, at least about 0.02%, at least about 0.05%, at least about 0.1%, at least about 0.2%, or at least about 0.5%) by weight to at most about 1% (e.g., at most about 0.8%, at most about 0.6%, at most about 0.5%, at most about 0.4%, at most about 0.2%, at most about 0.1%, at most about 0.05%, at most about 0.02%, at most about 0.01%, or at most about 0.005%) by weight of the polishing composition described herein.

In one or more embodiments, the polishing composition described herein can optionally include at least one (e.g., two or three) oxidizer. In one or more embodiments, the polishing composition optionally includes a single oxidizer. In some embodiments, an oxidizer can be added when diluting a concentrated composition to form a POU composition. The oxidizer can be selected from the group consisting of hydrogen peroxide, ammonium persulfate, silver nitrate (AgNO₃), ferric nitrates or chlorides, per acids or salts, ozone water, potassium ferricyanide, potassium dichromate, potassium iodate, potassium bromate, potassium periodate, periodic acid, vanadium trioxide, hypochlorous acid, sodium hypochlorite, potassium hypochlorite, calcium hypochlorite, magnesium hypochlorite, ferric nitrate, potassium permanganate, other inorganic or organic peroxides, and mixtures thereof. In some embodiments, the oxidizer is hydrogen peroxide.

In some embodiments, the oxidizer is in an amount of from at least about 0.05% (e.g., at least about 0.1%, at least about 0.2%, at least about 0.4%, at least about 0.5%, at least about 1%, at least about 1.5%, at least about 2%, at least about 2.5%, at least about 3%, at least about 3.5%, at least about 4%, or at least about 4.5%) by weight to at most about 5% (e.g., at most about 4.5%, at most about 4%, at most about 3.5%, at most about 3%, at most about 2.5%, at most about 2%, at most about 1.5%, at most about 1%, at most about 0.5%, or at most about 0.1%) by weight of the polishing composition described herein. In some embodiments, the oxidizer may reduce the shelf life of a polishing composition. In such embodiments, the oxidizer can be added to the polishing composition at the point of use right before polishing.

In some embodiments, the polishing composition described herein can include a solvent (e.g., a primary solvent), such as water. In some embodiments, the solvent (e.g., water) is in an amount of from at least about 20% (e.g., at least about 25%, at least about 30%, at least about 35%, at least about 40%, at least about 45%, at least about 50%, at least about 55%, at least about 60%, at least about 65%, at least about 70%, at least about 75%, at least about 80%, at least about 85%, at least about 90%, at least about 92%, at least about 94%, at least about 95%, or at least about 97%) by weight to at most about 99% (e.g., at most about 98%, at most about 96%, at most about 94%, at most about 92%, at most about 90%, at most about 85%, at most about 80%, at most about 75%, at most about 70%, or at most about 65%) by weight of the polishing composition described herein.

In one or more embodiments, an optional secondary solvent (e.g., an organic solvent) can be used in the polishing composition (e.g., the POU or concentrated polishing composition) of the present disclosure, which can help with the dissolution of one or more components in the polishing composition (e.g., a guanamine compound or an azole-containing corrosion inhibitor). In one or more embodiments, the secondary solvent can be one or more alcohols, alkylene glycols, or alkylene glycol ethers. In one or more embodiments, the secondary solvent includes one or more solvents selected from the group consisting of ethanol, 1-propanol, 2-propanol, n-butanol, propylene glycol, 2-methoxyethanol, 2-ethoxyethanol, propylene glycol propyl ether, and ethylene glycol.

In some embodiments, the secondary solvent is in an amount of from at least about 0.0025% (e.g., at least about 0.005%, at least about 0.01%, at least about 0.02%, at least about 0.05%, at least about 0.1%, at least about 0.2%, at least about 0.4%, at least about 0.6%, at least about 0.8%, or at least about 1%) by weight to at most about 2% (e.g., at most about 1.8%, at most about 1.6%, at most about 1.5%, at most about 1.4%, at most about 1.2%, at most about 1%, at most about 0.8%, at most about 0.6%, at most about 0.5%, or at most about 0.1%) by weight of the polishing composition described herein.

In one or more embodiments, the polishing composition described herein can be substantially free of one or more of certain ingredients, such as organic solvents, pH adjusting agents (e.g., organic acids, inorganic acids, organic bases, or inorganic bases), quaternary ammonium compounds (e.g., salts such as tetraalkylammonium salts and hydroxides such as tetramethylammonium hydroxide), alkali bases (such as alkali hydroxides), fluorine-containing compounds (e.g., fluoride compounds or fluorinated compounds (such as fluorinated polymers/surfactants)), silicon-containing compounds such as silanes (e.g., alkoxysilanes or amino silanes), nitrogen containing compounds (e.g., amino acids, amino alcohols, amines, alkylamines, or imines (e.g., amidines such as 1,8-diazabicyclo[5.4.0]-7-undecene (DBU) and 1,5-diazabicyclo[4.3.0]non-5-ene (DBN)), amides, or imides), salts (e.g., halide salts or metal salts), polymers (e.g., non-ionic, cationic, anionic, or water-soluble polymers), inorganic acids (e.g., hydrochloric acid, sulfuric acid, phosphoric acid, or nitric acid), surfactants (e.g., cationic surfactants, anionic surfactants, non-polymeric surfactants, zwitterionic surfactants, or non-ionic surfactants), plasticizers, oxidizing agents (e.g., hydrogen peroxide and periodic acid), corrosion inhibitors (e.g., azole, thiazole, or non-azole corrosion inhibitors), electrolytes (e.g., polyelectrolytes), and/or certain abrasives (e.g., polymeric abrasives, fumed silica, ceria abrasives, non-ionic abrasives, surface modified abrasives, negatively/positively charged abrasives, or ceramic abrasive composites). The halide salts that can be excluded from the polishing compositions include alkali metal halides (e.g., sodium halides or potassium halides) or ammonium halides (e.g., ammonium chloride), and can be fluorides, chlorides, bromides, or iodides. As used herein, an ingredient that is “substantially free” from a polishing composition refers to an ingredient that is not intentionally added into the polishing composition. In some embodiments, the polishing composition described herein can have at most about 1000 ppm (e.g., at most about 500 ppm, at most about 250 ppm, at most about 100 ppm, at most about 50 ppm, at most about 10 ppm, or at most about 1 ppm) of one or more of the above ingredients that are substantially free from the polishing composition. In some embodiments, the polishing compositions described herein can be completely free of one or more of the above ingredients.

The present disclosure also contemplates a method of using any of the above-described polishing compositions (e.g., concentrates or POU slurries). With the concentrate, the method can include the steps of diluting the concentrate to form a POU slurry (e.g., by a factor of at least two), and then contacting a substrate surface at least partially comprising tungsten or molybdenum with the POU slurry. In some embodiments, an oxidizer can be added to the slurry before or after the dilution. With the POU slurry, the method can include the step of contacting the substrate surface at least partially comprising tungsten or molybdenum with the polishing composition.

In one or more embodiments, this disclosure features a polishing method that can include applying a polishing composition according to the present disclosure to a surface of a substrate (e.g., a wafer having at least tungsten or molybdenum on the surface of the substrate); and bringing a pad into contact with the surface of the substrate and moving the pad in relation to the substrate. Further, in some embodiments, after polishing a substrate with a polishing composition described herein, the polished substrate can undergo a rinse polishing process where a composition including all the components of the polishing composition described herein, except the abrasive, is applied to the polished substrate in the polishing tool and the pad of the polishing tool is brought into contact with the substrate and moved in relation to the substrate to create a rinse polished substrate. In some embodiments, after the polishing process and/or the rinse polishing process, the substrate can be removed from the polishing tool and subjected to a post-CMP cleaning in a cleaning tool (e.g., a brush scrubber or a spin rinse dryer).

In some embodiments, the method that uses a polishing composition described herein can further include producing a semiconductor device from the substrate treated by the polishing composition through one or more steps. For example, photolithography, ion implantation, dry/wet etching, plasma ashing, deposition (e.g., PVD, CVD, ALD, ECD), wafer mounting, die cutting, packaging, and testing can be used to produce a semiconductor device from the substrate treated by the polishing composition described herein.

The specific examples below are to be construed as merely illustrative, and not limitative of the remainder of the disclosure in any way whatsoever. Without further elaboration, it is believed that one skilled in the art can, based on the description herein, utilize the present invention to its fullest extent.

### EXAMPLES

In these examples, the polishing was performed on 200 mm wafers, using an AMAT Mirra CMP polisher, a Fujibo H804 pad, a downforce pressure of 1-2 psi, a platen head velocity between 50/45 and 120/112 rpm, and a slurry flow rate between of 175 mL/min and 225 mL/min. The static etch rate (SER) experiments were performed by immersing a tungsten or molybdenum coupon in 100 grams of the polishing composition for five minutes at a temperature of 60° C. and using four-point probe measurements or concentration of metal ions in solution to arrive at A/min values.

The general compositions used in the examples are shown in Table 1 below. The specifics details on the differences in the compositions tested will be explained in further detail when discussing the respective examples.

TABLE 1

| Component | % By Weight of Composition |
|---|---|
| pH adjuster | 0.05-5 |
| Amino Acid | 0.005-1 (if used) |
| Guanamine Compound | 0.001-0.1 (if used) |
| Abrasive (silica) | 0.1-12 |
| Oxidizer | 0.01-5 (if used) |
| Solvent (DI Water) | 80-99 |
| pH | 2-7 |
| Organic Solvent | 0.005-1 (if used) |

### Example 1

Table 2 below shows the tungsten static etch rate (W SER), molybdenum static etch rate (Mo SER), and the removal rates (RR) for silicon oxide (TEOS), silicon nitride (SiN), polysilicon (pSi), tungsten (W), and molybdenum (Mo) films for six different example compositions. Example 1 is a control sample that does not include any guanamine compound. Examples 2-6 had the same composition as Example 1 except each had a guanamine compound added. The guanamine compounds (i.e., G1-G5) in Examples 2-6 are all distinct from each other, were all added at the same weight percent, and are all encompassed by formula (I) in the Detailed Description. The silica used as an abrasive in this example had no chemical modification of the surface. An amino acid and oxidizer were included in each of the formulations at the same weight percent, but no organic solvent was included.

TABLE 2

| | Ex. 1 (no | Ex. 2 | Ex. 3 | Ex. 4 | Ex. 5 | Ex. 6 |
|---|---|---|---|---|---|---|
| | Guanamine) | (G1) | (G2) | (G3) | (G4) | (G5) |
| W SER | 4.4 | 0.05 | 4.42 | 4.24 | 4.52 | 2.61 |
| (Å/min) | | | | | | |
| Mo SER | 81.9 | 21.8 | 69.5 | 56.3 | 75.5 | 13.4 |
| (Å/min) | | | | | | |
| TEOS RR | 836 | 971 | 723 | 1024 | 972 | 940 |
| (Å/min) | | | | | | |
| SiN RR | 111 | 108 | 101 | 122 | 125 | 95 |
| (Å/min) | | | | | | |
| pSi RR | 28 | 26 | 49 | 50 | 47 | 125 |
| (Å/min) | | | | | | |
| W RR | 352 | 330 | 353 | 323 | 335 | 316 |
| (Å/min) | | | | | | |
| Mo RR | 384 | 380 | 383 | 426 | 415 | 227 |
| (Å/min) | | | | | | |

The results show, surprisingly, that the inclusion of the guanamine compounds were able to reduce the SER on Mo coupons between about 8% (Ex. 5) and 84% (Ex. 6) when compared with the value obtained for Example 1. Additionally, the inclusion of the guanamine compound was able to either maintain the SER on W coupons (Examples 3-5) or significantly reduce the SER (Examples 2 and 6). Importantly, neither the W RR nor the Mo RR were significantly decreased with the addition of the guanamine compound, which combined with the lower SER values suggests a more controlled and defect free polishing process when compared with using the polishing composition of Example 1.

### Example 2

Table 3 below shows the tungsten static etch rate (W SER), molybdenum static etch rate (Mo SER), and the removal rates (RR) for TEOS, SiN, tungsten, and molybdenum films for four different example compositions. Example 7 is a control sample that does not include any guanamine compound. Examples 8-10 had the same composition as Example 7 except each had different loadings of the same guanamine compound (G6) added. The guanamine compound used in Examples 8-10 is distinct from those added in the Examples of Table 2 and is encompassed by formula (I) in the Detailed Description. The silica used as an abrasive in this example had a sulfonic acid chemical modification of the surface resulting in a negative surface charge. An organic solvent was included in these formulations, but no oxidizer or amino acid were included.

TABLE 3

| | Ex. 7 | Ex. 8 | Ex. 9 | Ex. 10 |
|---|---|---|---|---|
| | (no | (20 ppm | (40 ppm | (160 ppm |
| | Guanamine) | G6) | G6) | G6) |
| W SER (Å/min) | 0.45 | 0.2 | 0.17 | 0.04 |
| Mo SER | 1.10 | 0.86 | 0.62 | 0.44 |
| (Å/min) | | | | |
| TEOS RR | 32 | 31 | 34 | 39 |
| (Å/min) | | | | |
| SiN RR | 474 | 416 | 397 | 360 |
| (Å/min) | | | | |
| Mo RR (Å/min) | 36 | 24 | 31 | 59 |
| W RR (Å/min) | 39 | 56 | 45 | 44 |

The results show, surprisingly, that the inclusion of the guanamine compound was able to reduce the SER on Mo and W coupons progressively as the amount of guanamine compound was increased. Importantly, neither the W RR nor the Mo RR were significantly decreased with the addition of the guanamine compound, which combined with the lower SER values suggests a more controlled and defect free polishing process when compared with using the polishing composition of Example 7.

Although only a few example embodiments have been described in detail above, those skilled in the art will readily appreciate that many modifications are possible in the example embodiments without materially departing from this invention. Accordingly, all such modifications are intended to be included within the scope of this disclosure as defined in the following claims.

What is claimed is:

1. A polishing composition comprising:
at least one abrasive;
at least one pH adjuster selected from the group consisting of an acid, a base, or a mixture thereof;
at least one guanamine compound, wherein the guanamine compound comprises a structure of formula (I): 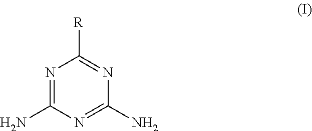
or a salt thereof,
wherein R is a group that comprises an optionally substituted aliphatic (e.g., optionally substituted alkyl), optionally substituted aromatic (e.g., optionally substituted aryl), or optionally substituted heterocyclic (e.g., optionally substituted triazinyl), or optionally substituted aromatic-aliphatic (e.g., optionally substituted arylalkyl); and
water.

2. The polishing composition of claim 1, wherein the at least one abrasive is selected from the group consisting of cationic abrasives, substantially neutral abrasives, and anionic abrasives.

3. The polishing composition of claim 1, wherein the at least one abrasive is selected from the group consisting of alumina, silica, titania, ceria, zirconia, co-formed products of alumina, silica, titania, ceria, or zirconia, coated abrasives, surface modified abrasives, and mixtures thereof.

4. The polishing composition of claim 1, wherein the at least one abrasive is in an amount of from about 0.05 wt % to about 50 wt % of the composition.

5. The polishing composition of claim 1, wherein the acid is selected from the group consisting of gluconic acid, lactic acid, citric acid, tartaric acid, malic acid, glycolic acid, malonic acid, formic acid, oxalic acid, acetic acid, propionic acid, peracetic acid, succinic acid, amino acetic acid, phenoxyacetic acid, bicine, diglycolic acid, glyceric acid, tricine, alanine, histidine, valine, isoleucine, leucine, methionine, phenylalanine, cysteine, selenocysteine, glycine, proline, serine, threonine, asparagine, glutamine, aspartic acid, glutamic acid, arginine, histidine, lysine, tyrosine, tryptophan, benzoic acid, 1,2-ethanedisulfonic acid, 4-amino-3-hydroxy-1-naphthalenesulfonic acid, 8-hydroxyquinoline-5-sulfonic acid, aminomethanesulfonic acid, benzenesulfonic acid, hydroxylamine O-sulfonic acid, methanesulfonic acid, m-xylene-4-sulfonic acid, poly(4-styrenesulfonic acid), polyanetholesulfonic acid, p-toluenesulfonic acid, trifluoromethane-sulfonic acid, ethyl phosphoric acid, cyanoethyl phosphoric acid, phenyl phosphoric acid, vinyl phosphoric acid, poly(vinylphosphonic acid), 1-hydroxyethane-1,1-diphosphonic acid, nitrilotri(methylphosphonic acid), diethylenetriaminepentakis (methylphosphonic acid), N,N,N′,N′-ethylenediaminetetrakis(methylene phosphonic acid), n-hexylphosphonic acid, benzylphosphonic acid, phenylphosphonic acid, salts thereof, and mixtures thereof.

6. The polishing composition of claim 1, wherein the base is selected from the group consisting inorganic bases, organic bases, and mixtures thereof.

7. The polishing composition of claim 1, wherein the pH adjuster is in an amount of from about 0.001% to about 10% by weight of the composition.

8. The polishing composition of claim 1, wherein R in formula (I) is a substituted or unsubstituted C₁-C₂₀ alkyl group, a substituted or unsubstituted C₂-C₂₀ alkenyl group, a substituted or unsubstituted cycloalkyl group, or a substituted or unsubstituted aryl group.

9. The polishing composition of claim 1, wherein the guanamine compound is selected from the group consisting of butyroguanamine, acetoguanamine, benzoguanamine, caprinoguanamine, adipoguanamine, stearoguanamine, 2,4-diamine-6-nonyl-1,3,5-triazine, 2,4-diamino-6-undecyl-1,3,5-triazine, 3,9-bis[2-(3,5-diamino-2,4,6-triazaphenyl)ethyl]-2,4,8,10-tetraoxaspiro[5.5]undecane, 2,4-diamino-6-butylamino-1,3,5-triazine, 2,4-diamino-6-(4-methylphenyl)-1,3,5-triazine, 2,4-diamino-6-[2-(2-methyl-1-imidazolyl)ethyl]-1,3,5-triazine, 2,4-diamino-6-[2-(2-undecyl-1-imidazolyl)ethyl]-1,3,5-triazine, and mixtures thereof.

10. The polishing composition of claim 1, wherein the guanamine compound comprises a structure of formula (IA): 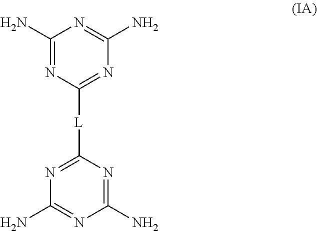
or a salt thereof,
wherein L is a linker (e.g., optionally substituted aliphatic, optionally substituted heteroaliphatic, or a combination thereof).

11. The polishing composition of claim 10, wherein L is 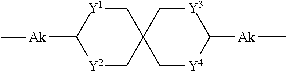
or -Ak-; each Ak is, independently, a covalent bond, optionally substituted aliphatic (e.g., optionally substituted alkylene), or optionally substituted heteroaliphatic (e.g., optionally substituted heteroalkylene); and each of Y¹, Y², Y³, and Y⁴ is, independently, alkylene (e.g., —CR^{C1}R^{C2}—), oxy (—O—), thio (—S—), or imino (—NR^{N1}—).

12. The polishing composition of claim 1, wherein the guanamine compound is in an amount of from about 0.1 ppm to about 1000 ppm of the composition.

13. The polishing composition of claim 1, further comprising at least one amino acid or poly(amino acid), wherein the amino acid is chemically distinct from the pH adjuster.

14. The polishing composition of claim 13, wherein the amino acid or poly(amino acid) is in an amount of from about 0.001% to about 1% by weight of the composition.

15. The polishing composition of claim 1, further comprising a nitride inhibiting compound comprising:
a hydrophobic portion comprising a C₄ to C₄₀ hydrocarbon group; and
a hydrophilic portion comprising at least one group selected from the group consisting of a sulfinate group, a sulfate group, a sulfonate group, a carboxylate group, a phosphate group, and a phosphonate group; and
wherein the hydrophobic portion and the hydrophilic portion are separated by zero to ten alkylene oxide groups.

16. The polishing composition of claim 15, wherein the compound is in an amount of from about 0.1 ppm to about 1000 ppm of the composition.

17. The polishing composition of claim 1, wherein the polishing composition has a pH of from about 2 to about 7.

18. A method of polishing a substrate, comprising the steps of:
applying the polishing composition of claim 1 to a surface of a substrate; and
bringing a pad into contact with the surface of the substrate and moving the pad in relation to the substrate.

19. The method of claim 18, wherein the surface of the substrate comprises Mo and/or W.

20. The method of claim 18, further comprising forming a semiconductor device from the substrate.
